(19) United States
(12) Patent Application Publication
(10) Pub. No.: US 2026/0068182 A1
(43) Pub. Date: Mar. 5, 2026

(54) THROUGH SILICON VIA (TSV) BUS COMPRESSION-REDISTRIBUTION DIE FOR HIGH-BANDWIDTH THREE-DIMENSIONAL DYNAMIC RANDOM-ACCESS MEMORY (3D DRAM) FOR FLEXIBLE PROCESSING UNIT (PU) PLACEMENT, IMPROVED THERMAL, AND KNOWN GOOD DIE (KGD) DRAM PLACEMENT FOR HIGH-YIELD

(71) Applicant: QUALCOMM Incorporated, San Diego, CA (US)

(72) Inventors: Mustafa BADAROGLU, San Diego, CA (US); Roger BOOTH, San Diego, CA (US); Woo Tag KANG, San Diego, CA (US); Jihong CHOI, San Diego, CA (US); Zhongze WANG, San Diego, CA (US); Giridhar NALLAPATI, San Diego, CA (US); Periannan CHIDAMBARAM, San Diego, CA (US)

(21) Appl. No.: 19/312,791

(22) Filed: Aug. 28, 2025

Related U.S. Application Data
(60) Provisional application No. 63/689,348, filed on Aug. 30, 2024.

(51) Int. Cl. H10B 80/00; G11C 7/10; H01L 25/00; H01L 25/065; H01L 25/18

(52) U.S. Cl. CPC H10B 80/00; G11C 7/1048; G11C 2207/102; G11C 2207/107

(57) ABSTRACT

A three-dimensional (3D) stacked memory package is described. The 3D stacked memory package includes a base die. The 3D stacked memory package also includes memory dies stacked on the base die and including through silicon vias (TSVs) at a first pitch. The 3D stacked memory package also a compression-redistribution die between the memory dies and the base die. The compression-redistribution die includes second TSVs at a second pitch greater than the first pitch.

### CROSS-REFERENCE TO RELATED APPLICATION

The present Application for Patent claims the benefit of U.S. Provisional Patent Application No. 63/689,348 entitled “THROUGH SILICON VIA (TSV) BUS COMPRESSION/REDISTRIBUTION DIE FOR HIGH-BANDWIDTH THREE-DIMENSIONAL DYNAMIC RANDOM-ACCESS MEMORY (3D DRAM) FOR FLEXIBLE PROCESSING UNIT (PU) PLACEMENT, IMPROVED THERMAL, AND KNOWN GOOD DIE (KGD) DRAM PLACEMENT FOR HIGH-YIELD,” filed Aug. 30, 2024, assigned to the assignee hereof, and expressly incorporated herein by reference in its entirety.

### BACKGROUND OF THE DISCLOSURE

### 1. Field of the Disclosure

Aspects of the present disclosure relate to semiconductor memory devices and, more particularly, to a through silicon via (TSV) bus compression-redistribution die for high-bandwidth three-dimensional dynamic random-access memory (3D DRAM) for flexible processing unit (PU) placement, improved thermal, and known good die (KGD) DRAM placement for high-yield.

### 2. Description of the Related Art

Memory is a vital component for wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workloads. A semiconductor memory device solution for providing a high-capacity, low-latency, and high-bandwidth memory is a goal for system designers.

In practice, memory intensive applications (e.g., artificial intelligence (AI)) consume extensive amounts of dynamic random-access memory (DRAM). State of the art high-bandwidth memory (HBM) DRAM provides advantages in performance and power for memory-demanding workloads such as generative-AI. Implementation of high-bandwidth DRAM necessitates low-pitch through silicon via (TSV) connections because TSV connections should match to a base die. As a result, wafer-to-wafer stacking on the base die is utilized to support low-pitch TSV connections, which are matched to the base die.

Unfortunately, wafer-to-wafer stacking creates obstructions on the base die, limiting the placement of processing units (PUs) and a physical IO interface (PHY) on the base die due to the same die size matching requirement in each wafer stacked. In particular, the obstructions on the base die are caused by circuits (e.g., TSV/multiplexer (MUX)/driver) that are utilized by memory control circuits to access the TSVs and associated memory banks. Additionally, face-to-face (F2F) stacking of the high-bandwidth DRAM on the base die also limits the thermal performance of the base die. A TSV bus compression-redistribution die for high-bandwidth 3D DRAM, is desired.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

A three-dimensional (3D) stacked memory package is described. The 3D stacked memory package includes a base die, and a plurality of memory dies stacked on the base die. The plurality of memory dies includes a first plurality of through silicon vias (TSVs) at a first pitch. The 3D stacked memory package also includes a compression-redistribution die between the plurality of memory dies and the base die. The compression-redistribution die includes a second plurality of TSVs at a second pitch greater than the first pitch. A number of the first plurality of TSVs is different from a number of the second plurality of TSVs.

A method of forming a three-dimensional (3D) stacked memory package is described. The method includes stacking a plurality of memory dies on a compression-redistribution die supported by a base die. The plurality of memory dies includes a first plurality of TSVs at a first pitch. The method also includes forming a second plurality of TSVs in the compression-redistribution die at a second pitch greater than the first pitch. The method further includes forming compressor/redistributor blocks between the first plurality of TSVs and the second plurality of TSVs.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the FIGS. is provided for the purpose of illustration and description only and is not intended as a definition of the limits of the present disclosure. Other objects and advantages associated with the aspects disclosed herein will be apparent to those skilled in the art based on the accompanying drawings and detailed description.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), which includes a high-bandwidth three-dimensional (3D) stacked memory having a through silicon via (TSV) bus compression-redistribution die, in accordance with various aspects of the present disclosure.

FIGS. 2A and 2B illustrate perspective and layout views, respectively, of a high-bandwidth three-dimensional (3D) stacked memory package (300) connected through silicon via (TSV) bus.

FIG. 3 illustrates an extreme-bandwidth three-dimensional (3D) stacked memory package (300), having a through silicon via (TSV) bus compression-redistribution die, according to various aspects of the present disclosure.

FIGS. 4A to 4J illustrate a process of forming the extreme-bandwidth three-dimensional (3D) stacked memory package (300) of FIG. 3, having a through silicon via (TSV) bus compression-redistribution die, according to various aspects of the present disclosure.

FIGS. 5A to 5F illustrate a process of forming the extreme-bandwidth three-dimensional (3D) stacked memory package (300) of FIG. 3, having a through silicon via (TSV) bus compression-redistribution die, according to various aspects of the present disclosure.

FIG. 6 is a process flow diagram illustrating a method for forming an extreme-bandwidth three-dimensional (3D) stacked memory package (300), having a through silicon via (TSV) bus compression-redistribution die for flexible processing unit (PU) placement and improved thermal conductivity, according to various aspects of the present disclosure.

FIGS. 7A and 7B is a process flow diagram illustrating a method of an example implementation of the method illustrated in FIG. 6, according to various aspects of the present disclosure.

FIGS. 8A and 8B is another process flow diagram illustrating a method of an example implementation of the method illustrated in FIG. 6, according to various aspects of the present disclosure.

FIG. 9 various apparatuses (e.g., electronic devices) in which any of the semiconductor devices and/or electronic packages disclosed herein may be integrated, according to aspects of the disclosure.

FIG. 10 is a block diagram illustrating a design workstation used for circuit, layout, and logic design of a semiconductor component, such as the disclosed extreme-bandwidth three-dimensional (3D) stacked memory package (300).

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are three-dimensional (3D) stacked memory package and methods for fabricating the same. In an aspect, the 3D stacked memory package includes a base die, and a plurality of memory dies stacked on the base die. The plurality of memory dies includes a first plurality of through silicon vias (TSVs) at a first pitch. The 3D stacked memory package also includes a compression-redistribution die between the plurality of memory dies and the base die. The compression-redistribution die includes a second plurality of TSVs at a second pitch greater than the first pitch. A number of the first plurality of TSVs is different from a number of the second plurality of TSVs. In this way, obstructions on the base die is reduced or removed altogether. Also, thermal performance of the base die is enhanced.

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches, repeaters, and/or buffers. As described, the term “proximate” used throughout this description means “adjacent, very near, next to, or close to.” As described, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

Memory is a vital component for processing systems, such as wireless communications devices. For example, a cell phone may integrate memory as part of an application processor, such as a system-on-chip (SoC) including a central processing unit (CPU), a graphics processing unit (GPU), and a neural processing unit (NPU). Successful operation of some wireless applications depends on the availability of a high-capacity and low-latency memory solution for scalability of processor workloads. A semiconductor memory device solution for providing a high-capacity, low-latency, and high-bandwidth memory is an existing goal for system designers.

Semiconductor memory devices include, for example, static random-access memory (SRAM) and dynamic random-access memory (DRAM). In practice, memory intensive applications (e.g., artificial intelligence (AI) for large-language models and generative-AI) consume extensive amounts of data from DRAM. State of the art high-bandwidth (BW) memory (e.g., high-BW DRAM) provides advantages in performance and power for memory-demanding workloads such as generative-AI. Implementation of a high-BW DRAM stack is supported by a base die. Unfortunately, significant restrictions on the base die complicate the formation of a custom compute die for enhancing the capabilities of the high-BW DRAM stack.

In practice, high-BW DRAM necessitates low-pitch through silicon via (TSV) connections because TSV connections should match to a base die for delivering high-bandwidth data to the compute blocks on the base die. As a result, wafer-to-wafer stacking on a base die is utilized to support low-pitch TSV connections, which are matched to the base die. Unfortunately, wafer-to-wafer stacking creates obstructions on the base die, limiting the placement of processing units (PUs) and a physical IO interface (PHY) on the base die. In particular, the obstructions on the base die are caused by circuits (e.g., TSV/multiplexer (MUX)/drivers) that are utilized by a memory (e.g., DRAM) controller to access the TSVs and associated memory banks. Additionally, face-to-face (F2F) stacking with the base die also limits the thermal performance of the base die. To address these and other issues of the conventional high-BW DRAM stack, a TSV bus compression-redistribution die for high-bandwidth 3D DRAM, is desired.

Various aspects of the present disclosure are directed to TSV compression and/or redistribution at an intermediate die to resolve the obstruction problem due to the noted-memory control circuits on the base die. Some implementations relax the pitch scaling on the base die by utilizing a bus compression-redistribution that supports die-to-wafer stacking at a relaxed pitch (e.g., standard pitch). This TSV compression and/or redistribution technique also takes advantage of known good die (KGD) testing of DRAM cubes, therefore significantly improving stacked yield, by placing good (e.g., evaluated) DRAM cubes on verified locations of the base die. Additionally, the TSV compression and/or redistribution technique improves thermal performance because of a semiconductor (e.g., silicon (Si) buffer (e.g., a thermal buffer)) between the base die and the stack of memory dies (e.g., DRAM stack).

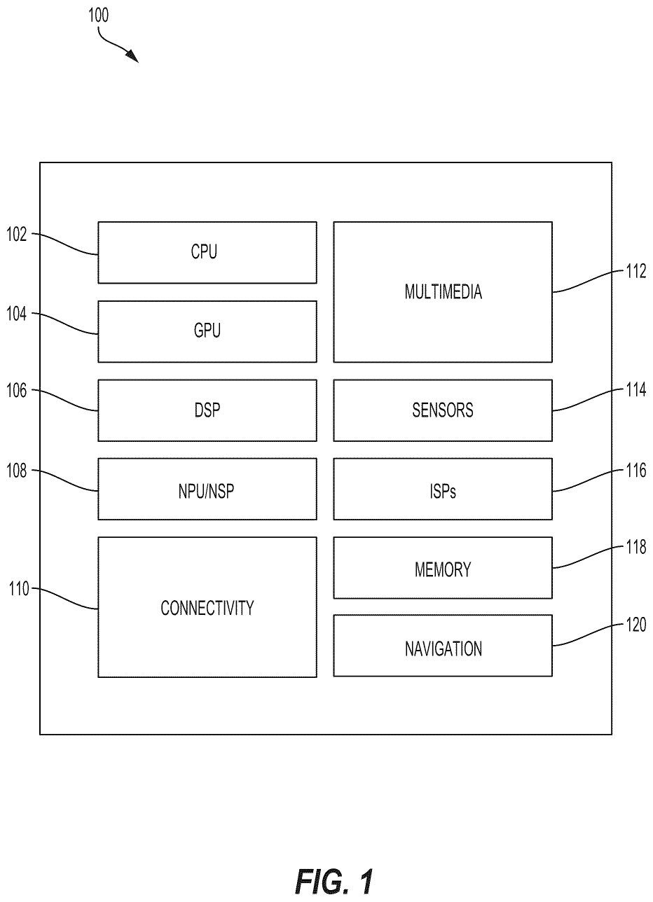

FIG. 1 illustrates an example implementation of a host system-on-chip (SoC) 100, which includes a high-bandwidth three-dimensional (3D) stacked memory having a through silicon via (TSV) bus compression-redistribution die, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

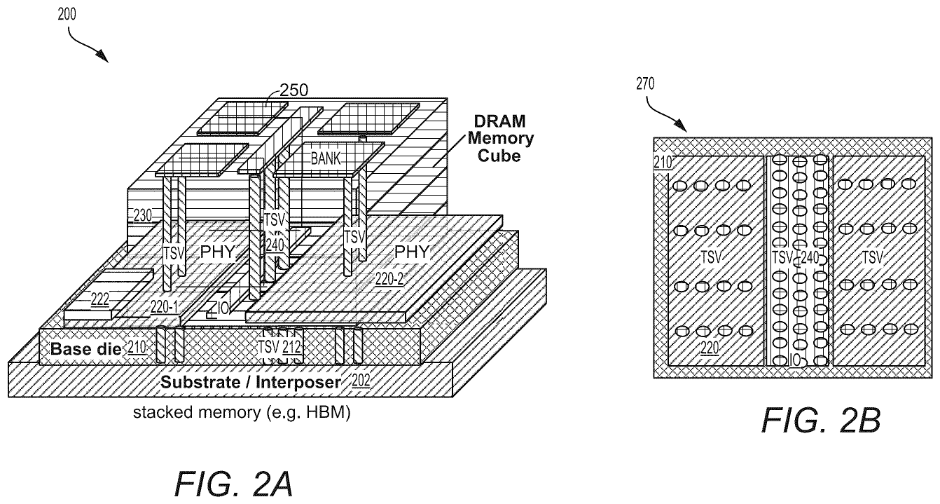

State of the art high-bandwidth (BW) dynamic random-access memory (DRAM) provides advantages in performance and power for memory-demanding workloads such as generative-AI. In practice, a high-BW DRAM stack is supported by a base die. Unfortunately, wafer-to-wafer stacking creates obstructions on the base die, limiting the placement of processing units (PUs) and a physical IO interface (PHY) on the base die. In particular, the obstructions on the base die are caused by circuits (e.g., through silicon via (TSV)/multiplexer (MUX)/drivers) that are utilized by a memory (e.g., DRAM) controller to access the TSVs and associated memory banks. Additionally, face-to-face (F2F) stacking with the base die limits the thermal performance of the base die. A TSV bus compression-redistribution die for high-bandwidth 3D DRAM, is illustrated, for example, in FIGS. 2A and 2B.

FIGS. 2A and 2B illustrate perspective and layout views, respectively, of a high-bandwidth three-dimensional (3D) stacked memory package (300) connected through silicon via (TSV) bus. As shown in FIG. 2A, an extreme-bandwidth 3D stacked memory package (300) 200 includes a base die 210 (e.g., a first die) that is supported by a package substrate/interposer 202. The base die 210 supports stacking of memory dies 230 (e.g., dynamic random-access memory (DRAM) dies) on the base die 210. In this example, the memory dies 230 are arranged using a back-to-face stacking of the DRAM dies on the face of the base die 210, according to a face-to-face (F2F) stacking. In some implementations, the base die 210 supports a stack of memory dies 230 (e.g., a stack of twelve (12) DRAM dies). The number of memory dies stacked on the base die 210 varies in different implementations.

The memory dies 230 include memory banks (BANK) and an input/output (IO) block that utilize signal through silicon vias (e.g., signal TSVs 240) extending through the memory dies 230 (e.g., second die) and landing on the base die 210. As shown in FIG. 2A, the signal TSVs 240 carry signal transmission between the memory dies 230 and a physical IO interface (PHY) 220 of the base die 210. Additionally, the base die 210 includes a logic/signal TSV 212 to provide communication between the PHY 220 as well as a processing unit (PU) 222 (e.g., CPU/GPU/NPU) and the package substrate/interposer 202.

FIG. 2B illustrates a layout view 270 of the base die 210, further illustrating the signal TSVs 240 (e.g., DRAM power TSV, DRAM signal TSV, and logic power TSV) connections, according to various aspects of the present disclosure. Conventional feedthrough TSV connections present a considerable number of obstacles to flexibly designing blocks on the base die 210 because the feedthrough TSV connections spread across an area defined by a shadow of the stack of memory dies 230. Additionally, significant thermal block restrictions on the base die 210 complicate placement of hot compute cores (e.g., the PU 222) on the base die 210.

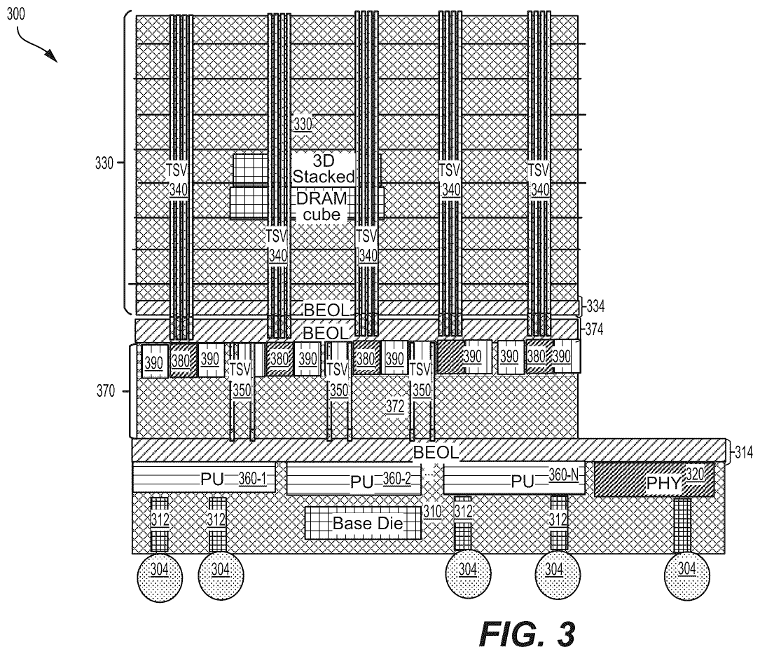

As shown in FIGS. 2A and 2B, wafer-to-wafer stacking creates obstructions on the base die 210, limiting the placement of processing units (PUs) and the PHY 220 on the base die 210. In particular, the obstructions on the base die are caused by circuits (e.g., TSV/MUX/drivers) that are utilized by a memory (e.g., DRAM) controller to access the TSVs and associated memory banks. Additionally, face-to-face (F2F) stacking with the base die 210 limits the thermal performance of the base die 210. A TSV bus compression-redistribution die for high-bandwidth 3D DRAM, is illustrated, for example, in FIG. 3.

FIG. 3 illustrates an extreme-bandwidth three-dimensional (3D) stacked memory package 300, having a through silicon via (TSV) bus compression-redistribution die, according to various aspects of the present disclosure. As shown in FIG. 3, the extreme-bandwidth 3D stacked memory package 300 includes a base die 310 that is contacted to package bumps 304 through the logic/signal TSV 312 coupled to an array of processing units (PUs) 360 (360-1, 360-2, . . . , 360-N) and a physical IO interface (PHY) 320. In various aspects of the present disclosure, the base die 310 supports stacking of memory dies 330 (e.g., dynamic random-access memory (DRAM) dies) on the base die 310. In this example, the memory dies 330 are arranged using a back-to-face stacking of the DRAM dies on the face of the base die 310, according to a face-to-face (F2F) stacking. The number of memory dies stacked on the base die 310 varies in different implementations.

In this example, the base die 310 includes an active layer 314 having a front-end-of-line (FEOL) layer (not shown), including transistors (Xtors), and a back-end-of-line (BEOL) layer on the FEOL layer. Similarly, the DRAM die 330 includes an active layer 334 having an FEOL layer (e.g., Xtors), and a BEOL layer contacted to the base die 310 through a compression-redistribution die 370 according to a face-to-face (F2F) stacking. According to various aspects to the present disclosure, the compression-redistribution die 370 is composed of a semiconductor material (e.g., silicon) to form a thermal buffer 372, which improves thermal conductivity of the extreme-bandwidth 3D stacked memory package 300.

As shown in FIG. 3, the extreme-bandwidth 3D stacked memory package 300 enables through silicon via (TSV) groups 340 to land on the compression-redistribution die 370 from the DRAM die 330. In practice, the TSV groups 340 are implemented using a fine-pitch (e.g., first pitch) for matching the TSV connections to the base die 310. According to various aspects of the present disclosure, the compression-redistribution die 370 is implemented with converter/redistributor blocks 390 to expand the pitch of the TSV groups 340 to provide a relaxed-pitch for a TSV 350 (e.g., second pitch) to land on the base die 310. That is, the second pitch can be greater than the first pitch. Also, the number of the TSVs of TSV groups 340 (e.g., first plurality of TSVs 340) can be different from a number of the TSVs 350 (e.g., second plurality of TSVs 350).

In various aspects of the present disclosure, the compression-redistribution die 370 includes converter/redistributor blocks 390 configured to provide the dual functions of a compression circuit and/or a redistribution metallization. The compression-redistribution die may be a die that includes circuitry configured to perform compression on the data received from the DRAM dies 330, redistribution of the signals between the DRAM dies 330 and the processing units (PUs) 360, or both. In an aspect, the compression circuit may include one or more parallel-to-serial converters. In some implementations, the parallel-to-serial converter of the converter/redistributor blocks 390 performs compression (e.g., reducing the number of TSVs), which enables a reduced number of TSVs that can be manufactured at a relaxed pitch for supporting a die-to-wafer stacking process. That is, each parallel-to-serial converter can be configured to convert multiple read signals received from multiple first TSVs 340 of the first plurality of TSVs 340 to a serial read signal sent to a second TSV 350 of the second plurality of TSVs 350. Processing units (PUs) 360 may be configured to receive the serial read signal through the second plurality of TSVs 350. In an aspect, the serial read signal can be synchronized to the PU (360) configured to receive the serial read signal. That is, the serial read signal may be clocked through the clock of the PUs 360. Additionally, the redistribution metallization of the converter/redistributor blocks 390 performs routing to accommodate the relaxed TSV pitch that a die-to-wafer stacking process supports and to optimally connect to the compute units on the base die.

Alternatively or in addition thereto, there can be one or more serial-to-parallel convertors may also be included, e.g., for writing. That is, each serial-to-parallel converter can be configured to convert a serial write signal, e.g., from a PU, received from a second TSV 350 to multiple write signals sent to the multiple first TSVs 340.

It is also contemplated that the compression circuit can perform data compression. An example of a data compression is a lossy compression. As an illustration, one or more least significant bits of data (e.g., of a word) may be dropped.

As shown in FIG. 3, the converter/redistributor blocks 390 of the compression-redistribution die 370 may be configured to perform an initial a parallel-to-serial compression to provide TSV compression. In this example, the converter/redistributor blocks 390 redistributes the TSVs to an optimal bus locations for optimal connection on the base die 310 as directed through the die-to-wafer stacking process with a relaxed TSV pitch and corresponding compute units. In this example, the converter/redistributor blocks 390 support a tight TSV pitch (e.g., fine-pitch) transition of the TSV groups 340 to a relaxed TSV pitch (e.g., standard pitch) of the TSV 350 in the compression-redistribution die 370.

In various aspects of the present disclosure, the converter/redistributor blocks 390 are configured as a TSV compression-redistribution structure between the stack of memory dies 330 and the base die 310. The TSV compression and/or redistribution functionality of the converter/redistributor blocks 390 operates in conjunction with a memory control circuit 380 of the compression-redistribution die 370. The memory control circuit 380 supports DRAM signaling/bank-select signals, as well as DRAM repair/MUX capability. Additionally, the memory control circuit 380 of the compression-redistribution die 370 supports DRAM known good die (KGD) testing in some implementations.

According to various aspects of the present disclosure, the TSV compression and/or redistribution provided by the converter/redistributor blocks 390 of the compression-redistribution die 370 resolves the obstruction problem caused by the memory control circuits on the base die 310. This TSV compression and/or redistribution technique provided by the compression-redistribution die 370 relaxes the pitch scaling on the base die 310 and allows die-to-wafer stacking at a relaxed pitch that takes advantage of KGD testing of the memory dies 330 (e.g., DRAM cube). Taking advantage of KGD testing significantly improves stacked yield, by placing verified (e.g., evaluated) DRAM cubes on verified locations of the base die 310.

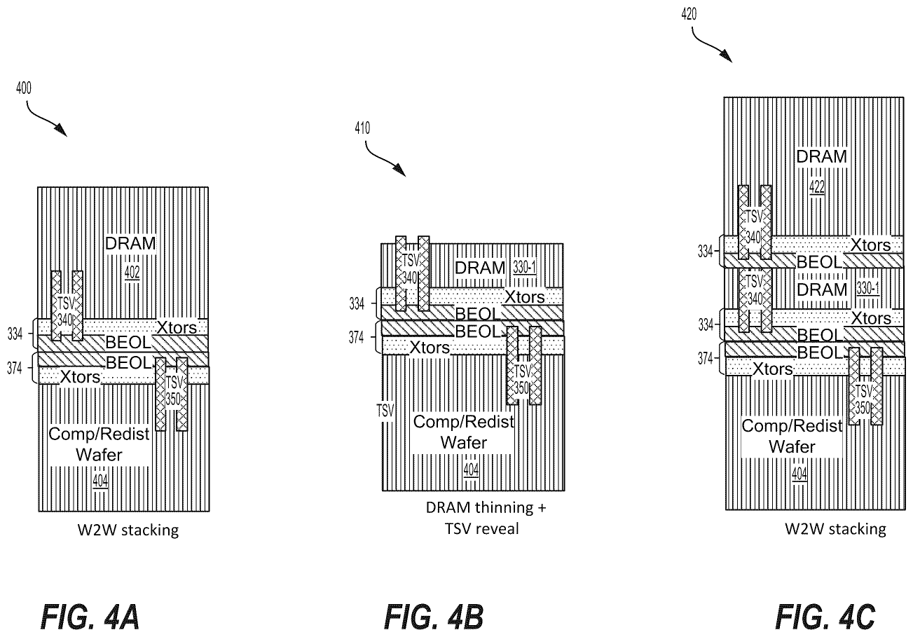

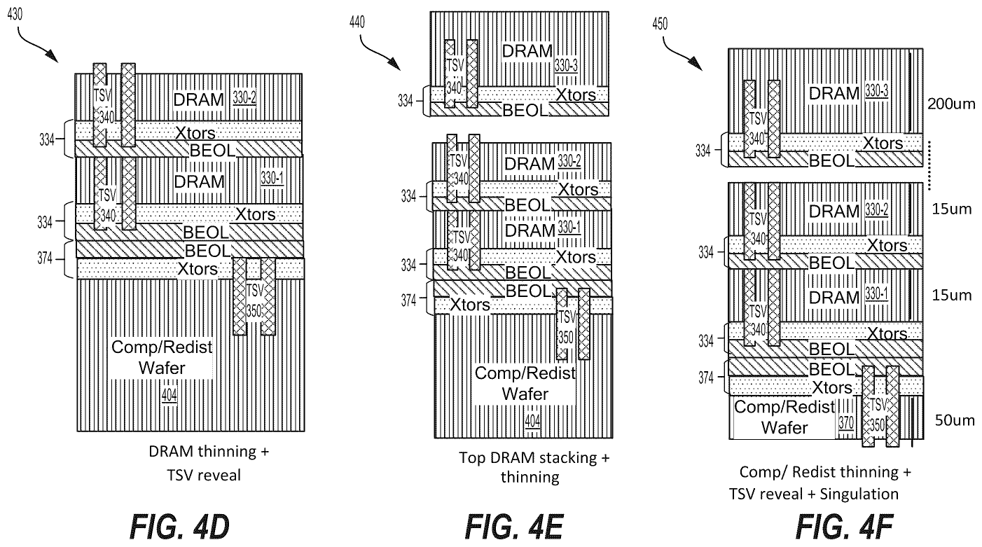

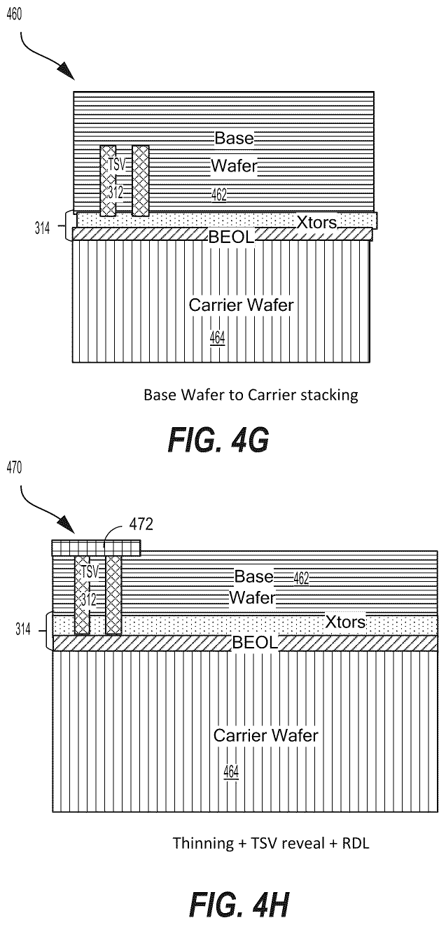

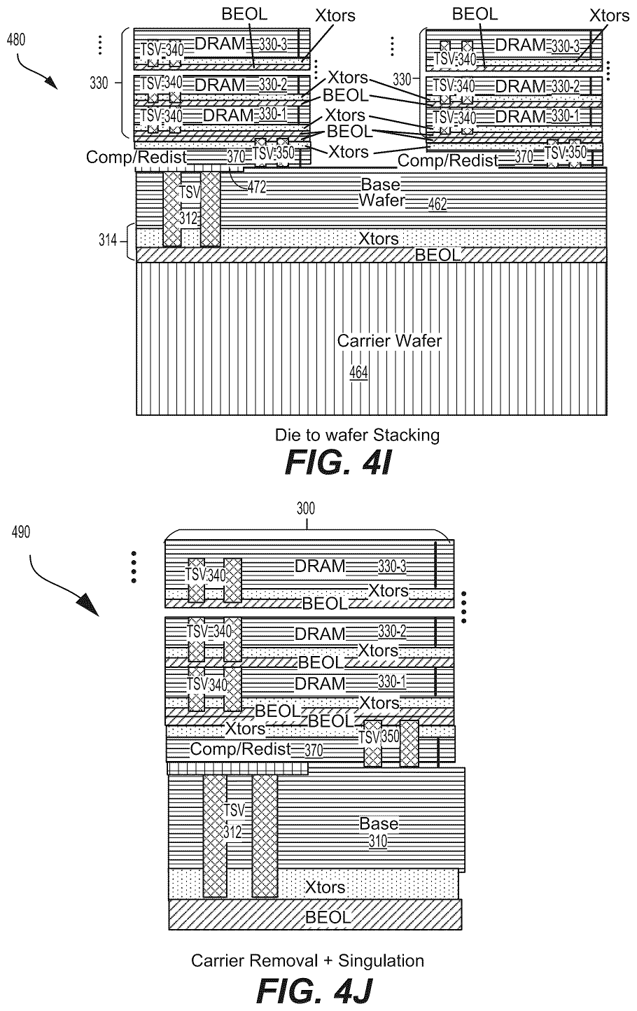

Additionally, the PHY 320 (and other circuits) may be placed at a side of the base die 310 for improved PU utilization on the base die 310. Removing the obstructions across the array of PUs 360 of the base die 310 yields improved one trillion floating-point operations per second (TFLOPS) performance. A process of forming an extreme-bandwidth three-dimensional (3D) stacked memory having a TSV bus compression-redistribution die is illustrated, for example, in FIGS. 4A to 4J.

FIGS. 4A to 4J illustrate a process of forming the extreme-bandwidth three-dimensional (3D) stacked memory package 300 of FIG. 3, having a through silicon via (TSV) bus compression-redistribution die, according to various aspects of the present disclosure. The process of forming the extreme-bandwidth 3D stacked memory package 300 of FIG. 3 begins in FIG. 4A.

FIG. 4A illustrates a first step 400 in the process of forming the extreme-bandwidth 3D stacked memory package 300 of FIG. 3, according to various aspects of the present disclosure. At the first step 400, a DRAM wafer-die 402 is stacked face-down on a compression-redistribution wafer-die 404 that is face-up according to a wafer-to-wafer (W2W) stacking. In this example, the compression-redistribution wafer-die 404 includes an active layer 374 having a front-end-of-line (FEOL) layer, including transistors (Xtors), and a back-end-of-line (BEOL) layer on the FEOL layer. Similarly, the DRAM wafer-die 402 includes an active layer 334 having an FEOL layer (e.g., Xtors), and a BEOL layer contacted to the BEOL layer of the compression-redistribution wafer-die 404, according to a face-to-face (F2F) stacking. It should be apparent to one of skill in the art that the compression-redistribution wafer-die 404 and/or the DRAM wafer-die 402 can include more than one FEOL layers and/or more than one BEOL layers. Nevertheless, to simplify and to avoid obscuring the illustration, only one FEOL layer and one BEOL layer are shown in each of the compression-redistribution wafer-die 404 and the DRAM wafer-die 402 in the current example.

In this example, a via-middle and redistribution layer (RDL) process forms the logic/signal TSV 312 (see FIG. 3) through the base die 310 and into the BEOL layer of the active layer 314 of the base die 310. Similarly, a via-middle and RDL process forms the TSV groups 340 through the DRAM die 330 and into the BEOL layer of the active layer 334 of the DRAM die 330.

FIG. 4B illustrates a second step 410 in the process of forming the extreme-bandwidth 3D stacked memory package 300 of FIG. 3, according to various aspects of the present disclosure. At the second step 410, the DRAM wafer-die 402 of FIG. 4A is thinned to form a first memory die 330-1, face-down (e.g., active layer 334) on the active layer 374 of the compression-redistribution wafer-die 404. In this example, thinning of the DRAM wafer-die 402 reveals the TSV groups 340 through a backside of the DRAM die 330.

FIG. 4C illustrates a third step 420 in the process of forming the extreme-bandwidth 3D stacked memory package 300 of FIG. 3, according to various aspects of the present disclosure. At the third step 420, a DRAM wafer-die 422 is stacked through wafer-to-wafer (W2W) stacking on the DRAM die 330, e.g., the first memory die 330-1. In this example, the DRAM wafer-die 422 includes an active layer 334 having an FEOL layer, including transistors (Xtors), and a BEOL layer on the FEOL layer. Additionally, a via-middle and RDL process forms the TSV groups 340 through the DRAM wafer-die 422 and into the BEOL layer of the active layer 334 of the DRAM wafer-die 422.

FIG. 4D illustrates a fourth step 430 in the process of forming the extreme-bandwidth 3D stacked memory package 300 of FIG. 3, according to various aspects of the present disclosure. At the fourth step 430, the DRAM wafer-die 422 of FIG. 4C is thinned to form a second memory die 330-2, face-down (e.g., active layer 334) on the first memory die 330-1. In this example, thinning of the DRAM wafer-die 422 reveals the TSV groups 340 through a backside of the second memory die 330-2.

FIG. 4E illustrates a fifth step 440 in the process of forming the extreme-bandwidth 3D stacked memory package 300 of FIG. 3, according to various aspects of the present disclosure. At the fifth step 440, a DRAM wafer-die is stacked through W2W stacking on the second memory die 330-2 and thinned to form a third memory die 330-3, face-down (e.g., active layer 334) on the second memory die 330-2. In this example, the via-last/via-middle and RDL process forms the TSV groups 340 through the third memory die 330-3, the FEOL layer and into the BEOL layer of the active layer 334 of the third memory die 330-3.

FIG. 4F illustrates a sixth step 450 in the process of forming the extreme-bandwidth 3D stacked memory package 300 of FIG. 3, according to various aspects of the present disclosure. At the sixth step 450, the compression-redistribution wafer-die 404 of FIG. 4E is thinned to form the compression-redistribution die 370. In this example, thinning of the compression-redistribution wafer-die 404 reveals the TSV 350 through the base die 310 and into the BEOL layer of the active layer 374 to expose the TSV 350 at a backside of the compression-redistribution die 370.

FIG. 4G illustrates a seventh step 460 in the process of forming the extreme-bandwidth 3D stacked memory package 300 of FIG. 3, according to various aspects of the present disclosure. At the seventh step 460, a base wafer-die 462 is stacked face-down on a carrier wafer 464. In this example, the base wafer-die 462 includes an active layer 314 having a front-end-of-line (FEOL) layer, including transistors (Xtors), and a back-end-of-line (BEOL) layer on the FEOL layer.

FIG. 4H illustrates an eighth step 470 in the process of forming the extreme-bandwidth 3D stacked memory package 300 of FIG. 3, according to various aspects of the present disclosure. At the eighth step 470, the base wafer-die 462 of FIG. 4G is thinned and arranged face-down, for example, having the active layer 314 on the carrier wafer 464. In this example, a via-last/via-middle and RDL process forms the logic/signal TSV 312 through the base wafer-die 462 and into the BEOL layer of the active layer 314 of the base wafer-die 462. In this example, an RDL 472 is formed on the backside of the base wafer-die 462 and contacted to the logic/signal TSV 312.

FIG. 4I illustrates a ninth step 480 in the process of forming the extreme-bandwidth 3D stacked memory package 300 of FIG. 3, according to various aspects of the present disclosure. At the ninth step 480, the DRAM die 330 and compression-redistribution die 370 stack formed at the step 450 are stacked through die-to-wafer (D2W) stacking on the base wafer-die 462 and contacted to the RDL 472.

FIG. 4J illustrates a last step 490 in the process of forming the extreme-bandwidth 3D stacked memory package 300 of FIG. 3, according to various aspects of the present disclosure. At the last step 490, the carrier wafer 464 is removed from the active layer 314 of the base wafer-die 462. Additionally, the base wafer-die 462 is singulated to complete formation of the extreme-bandwidth 3D stacked memory package 300 of FIG. 3, according to a face-down base die configuration.

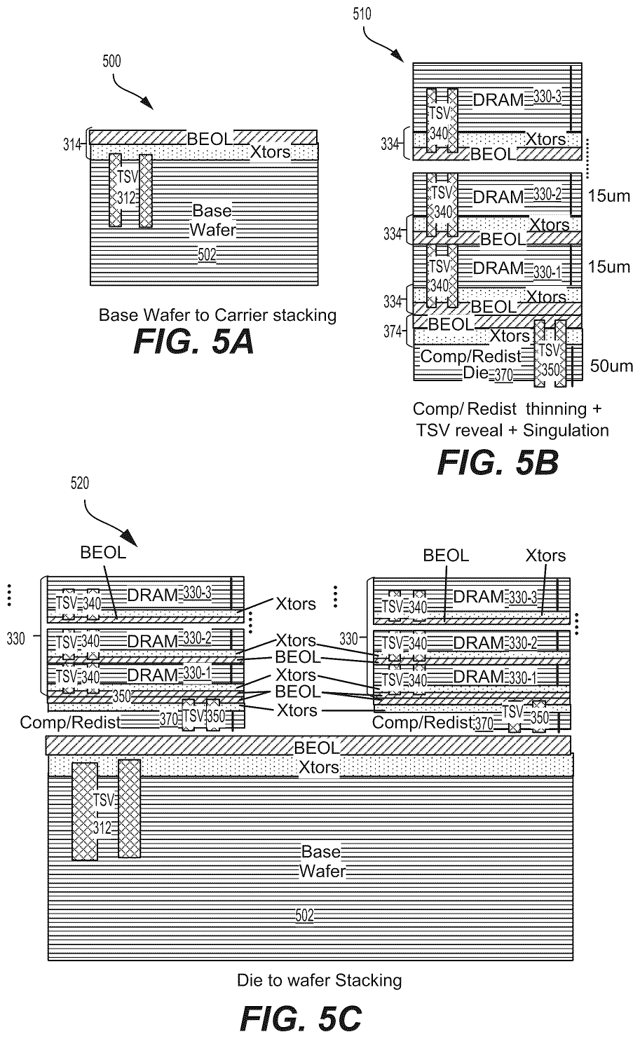

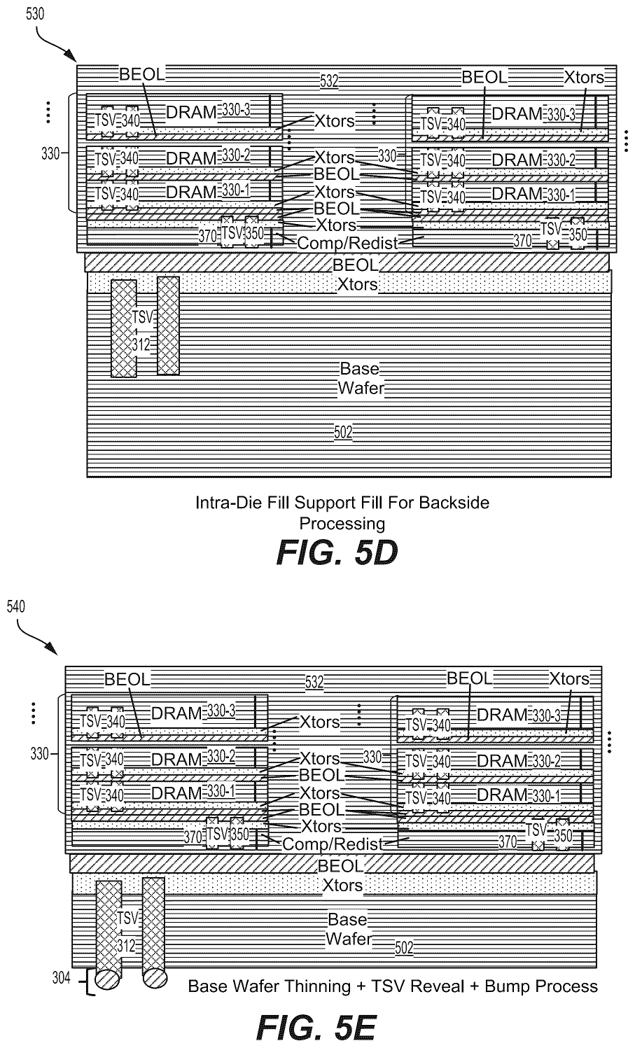

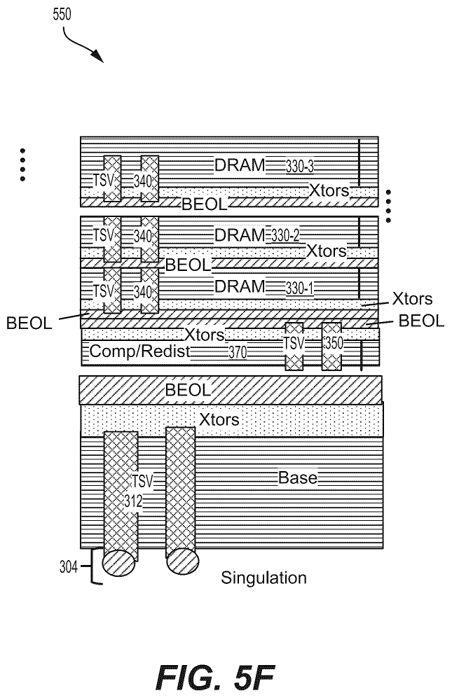

FIGS. 5A to 5F illustrate a process of forming the extreme-bandwidth three-dimensional (3D) stacked memory package 300 of FIG. 3, having a through silicon via (TSV) bus compression-redistribution die, according to various aspects of the present disclosure. The process of forming the extreme-bandwidth 3D stacked memory package 300 of FIG. 3 begins in FIG. 5A.

FIG. 5A illustrates a first step 500 in the process of forming the extreme-bandwidth 3D stacked memory package 300 of FIG. 3, according to various aspects of the present disclosure. At the first step 500, a base wafer-die 502 is formed face-up. In this example, the base wafer-die 502 includes an active layer 314 having a front-end-of-line (FEOL) layer, including transistors (Xtors), and a back-end-of-line (BEOL) layer on the FEOL layer.

FIG. 5B illustrates a second step 510 in the process of forming the extreme-bandwidth 3D stacked memory package 300 of FIG. 3, according to various aspects of the present disclosure. At the second step 510, the DRAM die 330 and the compression-redistribution die 370 stack are formed by following steps 400-450, as shown in FIGS. 4A-4F.

FIG. 5C illustrates a third step 520 in the process of forming the extreme-bandwidth 3D stacked memory package 300 of FIG. 3, according to various aspects of the present disclosure. At the third step 520, the DRAM die 330 and the compression-redistribution die 370 stack formed at step 450 are stacked through die-to-wafer (D2W) stacking on the base wafer-die 502, such that a backside of the compression-redistribution die 370 is on the active layer 314 of the base wafer-die 502.

FIG. 5D illustrates a fourth step 530 in the process of forming the extreme-bandwidth 3D stacked memory package 300 of FIG. 3, according to various aspects of the present disclosure. At the fourth step 530, an intra-die fill 532 is deposited on the base wafer-die 502 to enable backside processing.

FIG. 5E illustrates a fifth step 540 in the process of forming the extreme-bandwidth 3D stacked memory package 300 of FIG. 3, according to various aspects of the present disclosure. At the fifth step 540, the base wafer-die 502 is thinned. In this example, thinning of the base wafer-die 502 reveals the logic/signal TSV 312 through the base wafer-die 502 and into the BEOL layer of the active layer 314 to expose the logic/signal TSV 312 at a backside of the base wafer-die 502. Additionally, a bump process forms the package bumps 304 on a backside of the base wafer-die 502.

FIG. 5F illustrates a last step 550 in the process of forming the extreme-bandwidth 3D stacked memory package 300 of FIG. 3, according to various aspects of the present disclosure. At the last step 550, the base wafer-die 502 is singulated to complete formation of the extreme-bandwidth 3D stacked memory package 300 of FIG. 3, according to a face-up base die configuration.

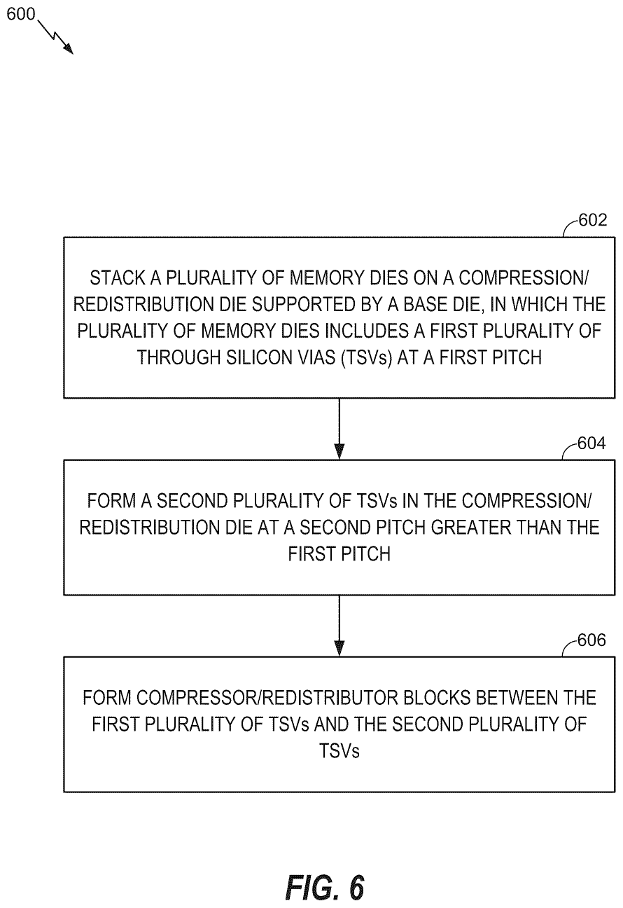

A process flow for forming an extreme-bandwidth three-dimensional (3D) stacked memory package having a through silicon via (TSV) bus compression/redistribution die for flexible processing unit (PU) placement and improved thermal conductivity is illustrated, for example, in FIG. 6.

FIG. 6 is a process flow diagram illustrating a method 600 for forming an extreme-bandwidth three-dimensional (3D) stacked memory package, having a through silicon via (TSV) bus compression-redistribution die for flexible processing unit (PU) placement and improved thermal conductivity, according to various aspects of the present disclosure.

As shown in FIG. 6, the method 600 beings at block 602, in which a plurality of memory dies are stack on a compression-redistribution die supported by a base die, in which the plurality of memory dies includes a first plurality of TSVs at a first pitch. For example, as shown in FIG. 3, the stacking of memory dies 330 forms a 3D stacked DRAM cube that is stacked on the compression-redistribution die 370.

At block 604, a second plurality of TSVs are formed in the compression-redistribution die at a second pitch greater than the first pitch. For example, as shown in FIG. 3, According to various aspects of the present disclosure, the compression-redistribution die 370 is implemented with converter/redistributor blocks 390 to expand the pitch of the TSV groups 340 to provide a relaxed-pitch for a TSV 350 (e.g., second pitch) to land on the base die 310.

At block 606, compressor/redistributor blocks are formed between the first plurality of TSVs and the second plurality of TSVs. For example, as shown in FIG. 3, the compression-redistribution die 370 includes converter/redistributor blocks 390 configured to provide the dual functions of a parallel-to-serial converter module and/or a redistribution metallization. In some implementations, the parallel-to-serial converter module of the converter/redistributor blocks 390 performs compression (e.g., reducing the number of TSVs), which enables a reduced number of TSVs that can be manufactured at a relaxed pitch for supporting a die-to-wafer stacking process. Additionally, the redistribution metallization of the converter/redistributor blocks 390 performs routing to accommodate a relaxed TSV pitch that a die-to-wafer stacking process supports and to optimally connect to the compute units on the base die.

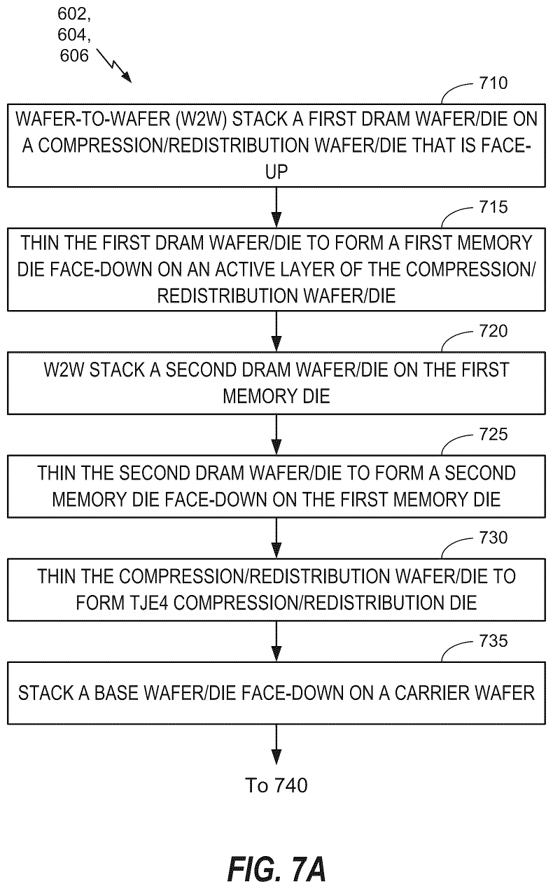

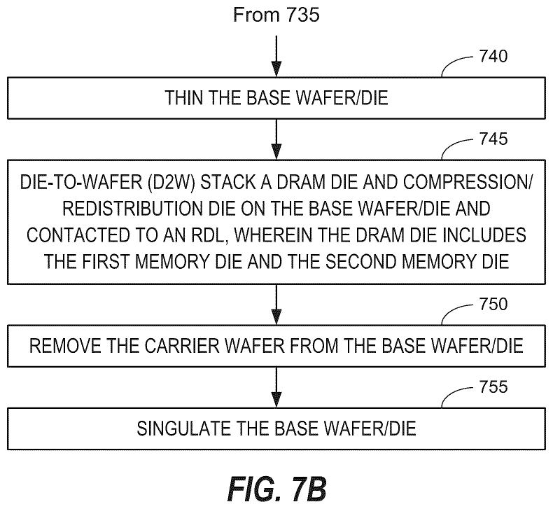

FIGS. 7A and 7B illustrate a process flow for a particular implementation of the blocks of FIG. 6. At block 710, a first DRAM wafer-die 402 can be wafer-to-wafer (W2W) stacked on a compression-redistribution wafer-die 404 that is face-up. Block 710 may correspond to FIG. 4A.

At block 715, the first DRAM wafer-die 402 thinned to form a first memory die 330-1 face-down on an active layer 374 of the compression-redistribution wafer-die 404. Block 715 may correspond to FIG. 4B.

At block 720, a second DRAM wafer-die 422 may be W2W stacked on the first memory die 330-1. Block 725 may correspond to FIG. 4C.

At block 725, the second DRAM wafer-die 422 may be thinned to form a second memory die 330-2 face-down on the first memory die 330-1. Block 725 may correspond to FIG. 4D. Note that blocks 720 and 725 may be repeated to form further stacked memory dies such as the third memory die 330-3 (e.g., see FIGS. 4E and 4F).

At block 730, the compression-redistribution wafer-die 404 may be thinned to form the compression-redistribution die 370. Block 730 may correspond to FIG. 4F.

At block 735, a base wafer-die 462 may be stacked face-down on a carrier wafer 464. Block 735 may correspond to FIG. 4G.

At block 740, the base wafer-die 462 may be thinned. Block 740 may correspond to FIG. 4H.

At block 745, a DRAM die 330 and the compression-redistribution die 370 may be die-to-wafer (D2W) stacked on the base wafer-die 462 and contacted to an RDL 472. The DRAM die 330 may include the stacked DRAMs (e.g., the first memory die 330-1, the second memory die 330-2, the third memory die 330-3, etc.). Block 745 may correspond to FIG. 4I.

At block 750, the carrier wafer 464 may be removed from the base wafer-die 462. Block 750 may correspond to FIG. 4J.

At block 755, the base wafer-die 462 may be singulated. Block 755 may also correspond to FIG. 4J.

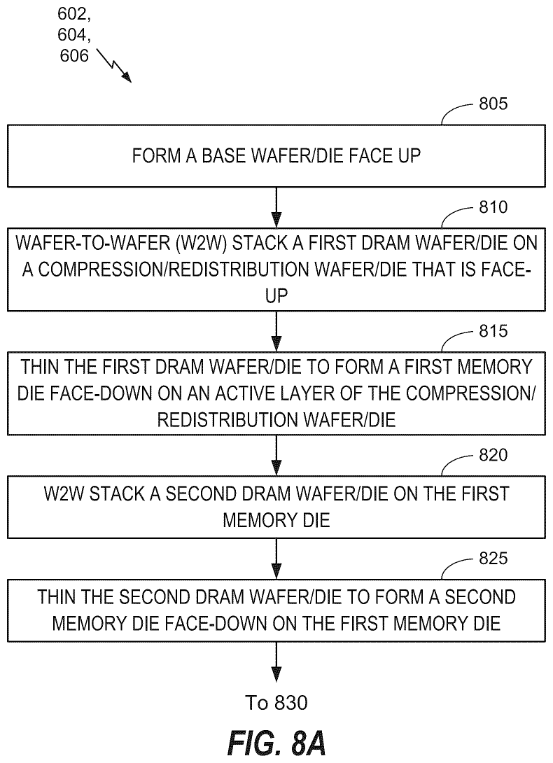

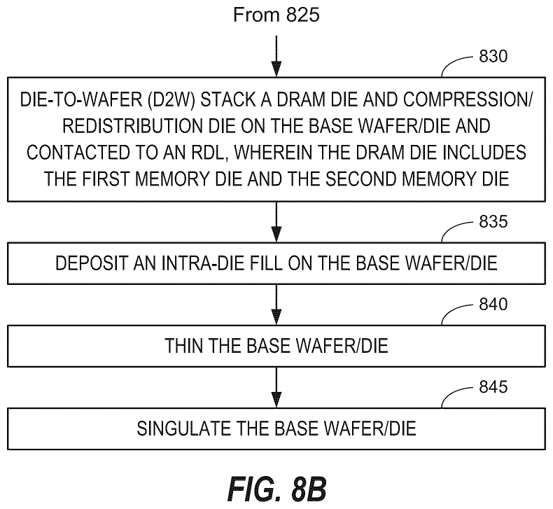

FIGS. 8A and 8B illustrate another process flow for a particular implementation of the blocks of FIG. 6. At block 805, a base wafer-die 502 may be formed face up. Block 805 may correspond to FIG. 5A.

Thereafter, processes similar to those illustrated in FIG. 4A-4F may be performed. That is, at block 810, a first DRAM wafer-die 402 can be wafer-to-wafer (W2W) stacked on a compression-redistribution wafer-die 404 that is face-up. Block 810 may correspond to FIG. 4A.

At block 815, the first DRAM wafer-die 402 thinned to form a first memory die 330-1 face-down on an active layer 374 of the compression-redistribution wafer-die 404. Block 815 may correspond to FIG. 4B.

At block 820, a second DRAM wafer-die 422 may be W2W stacked on the first memory die 330-1. Block 825 may correspond to FIG. 4C.

At block 825, the second DRAM wafer-die 422 may be thinned to form a second memory die 330-2 face-down on the first memory die 330-1. Block 825 may correspond to FIG. 4D. Note that blocks 820 and 825 may be repeated to form further stacked memory dies such as the third memory die 330-3 (e.g., see FIG. 5B).

At block 830, a DRAM die 330 and the compression-redistribution die 370 may be die-to-wafer (D2W) stacked on the base wafer-die 462 and contacted to an RDL 472. The DRAM die 330 may include the stacked DRAMs (e.g., the first memory die 330-1, the second memory die 330-2, the third memory die 330-3, etc.). Block 830 may correspond to FIG. 5C.

At block 835, an intra-die fill 532 may be deposited on the base wafer-die 502. Block 835 may correspond to FIG. 5D.

At block 840, the base wafer-die 462 may be thinned. Block 840 may correspond to FIG. 5E.

At block 845, the base wafer-die 462 may be singulated. Block 845 may also correspond to FIG. 5F.

The following should be noted regarding the flow indicated in FIG. 6-8. Unless otherwise indicated, the flow of blocks do not necessarily limit the ordering in which the blocks may be performed. In other words, the blocks may be performed in any order that is logical.

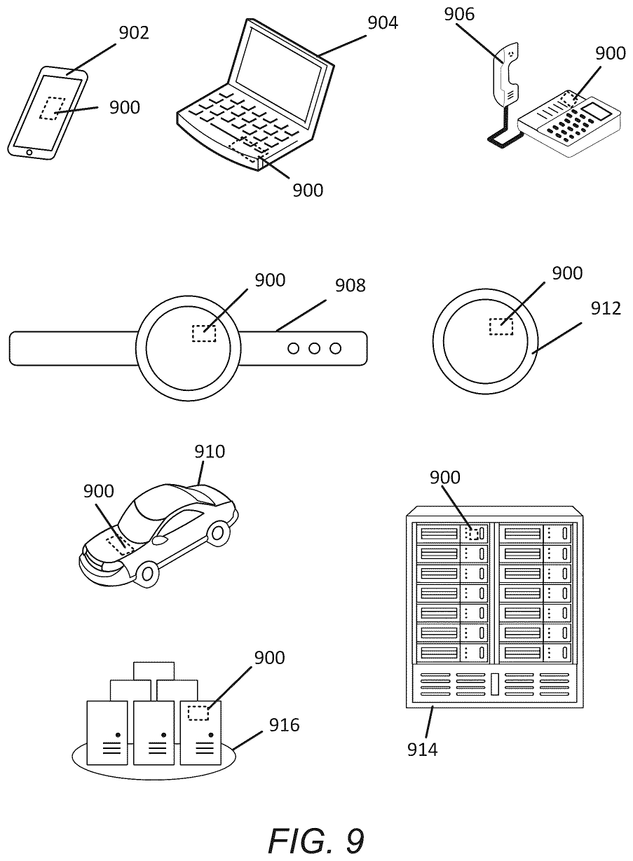

FIG. 9 illustrates various apparatuses (e.g., electronic devices) in which any of the semiconductor devices and/or electronic packages (e.g., 3D stacked memory packages) disclosed herein may be integrated, according to aspects of the disclosure. In an aspect, the semiconductor devices and/or electronic packages 900 may be integrated into user equipment (UE), including, by way of example and not limitation, a mobile phone device 902, a laptop computer device 904, a fixed-location terminal device 906, or a wearable device 908.

In other aspects, the semiconductor devices and/or electronic packages 900 may be integrated into electronic devices utilized in automotive applications. Such devices may include, by way of example and not limitation, sensors, controllers, processors, infotainment devices, and the like, which may be installed in a vehicle 910.

In yet other aspects, the semiconductor devices and/or electronic packages 900 may be integrated into a short-range device (SRD) 912. The SRD 912 may comprise, for example, one or more sensors, robotic machines, product code identifiers, electronic pricing and display labels, Internet of Things (IoT) devices, radio frequency identification (RFID) devices, Bluetooth Low Energy® (BLE) devices, or other similar devices.

In further aspects, the semiconductor devices and/or electronic packages 900 may be integrated into a server 914. The server 914 may comprise a computer system configured to provide services, data, or resources to other computers over a network. Such a server 914 may include one or more processors, integrated memory devices, power supplies, or other components mounted in one or more racks.

In yet other aspects, the semiconductor devices and/or electronic packages 900 may be integrated into a data center 916. The data center 916 may comprise a facility configured with one or more servers, storage devices, networking devices, and other supporting devices for storing, processing, and managing data.

The semiconductor devices and/or electronic packages 900 disclosed herein may be fabricated in various package configurations, including, but not limited to, side-by-side (S×S) packages, system-in-package (SiP) configurations, integrated circuit (IC) packages, package-on-package (PoP) devices, or any other suitable packaging configuration, whether disclosed herein or known in the art.

It will be appreciated, based on the teachings of the present disclosure, that the various apparatuses 902, 904, 906, 908, 910, 912, 914, and 916 illustrated in FIG. 9 are merely exemplary. Other apparatuses in which the semiconductor devices and/or electronic packages 900 may be integrated include, without limitation, mobile devices, hand-held personal communication system (PCS) units, portable data units (e.g., personal digital assistants), global positioning system (GPS)-enabled devices, navigation devices, set-top boxes, music players, video players, entertainment units, fixed-location data units, communication devices, smartphones, tablets, computers, wearable devices, servers, routers, memory devices, data centers, automotive electronic devices, Internet of Things (IoT) devices, or any combination thereof.

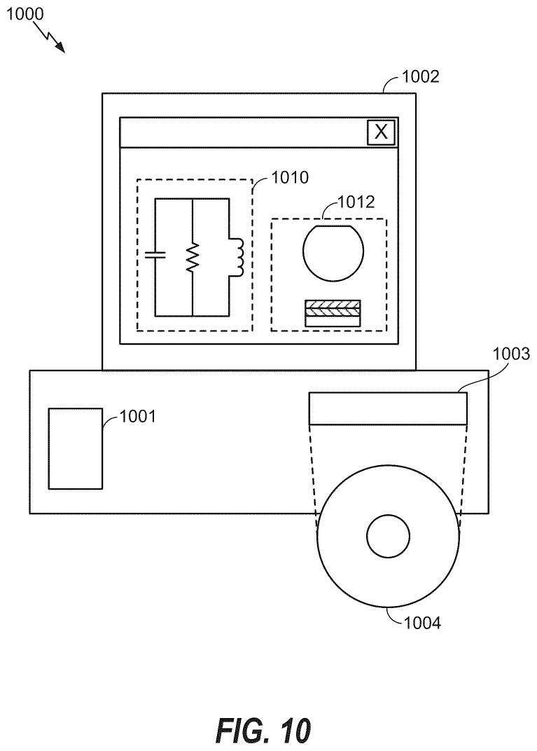

FIG. 10 is a block diagram illustrating a design workstation used for circuit, layout, and logic design of a semiconductor component, such as the extreme-bandwidth three-dimensional (3D) stacked memory package disclosed above. A design workstation 1000 includes a hard disk 1001 containing operating system software, support files, and design software such as Cadence or OrCAD. The design workstation 1000 also includes a display 1002 to facilitate design of a circuit 1010 or an integrated circuit (IC) component 1012, such as a high-bandwidth 3D stacked memory package. A storage medium 1004 is provided for tangibly storing the design of the circuit 1010 or the IC component 1012 (e.g., the high-bandwidth 3D stacked memory package). The design of the circuit 1010 or the IC component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the IC component 1012 by decreasing the number of processes for designing semiconductor wafers.

Implementation examples are described in the following numbered clauses:
1. A three-dimensional (3D) stacked memory package, comprising:
   a base die;
   a plurality of memory dies stacked on the base die, and including a first plurality of through silicon vias (TSVs) at a first pitch; and
   a compression-redistribution die between the plurality of memory dies and the base die, the compression-redistribution die including a second plurality of TSVs at a second pitch greater than the first pitch,
   wherein a number of the first plurality of TSVs is different from a number of the second plurality of TSVs.
2. The 3D stacked memory package of clause 1, wherein the compression-redistribution die comprises a redistribution metallization between the first plurality of TSVs and the second plurality of TSVs.
3. The 3D stacked memory package of any of clauses 1-2, wherein the compression-redistribution die comprises a compression circuit, a redistribution metallization, or both between the first plurality of TSVs at the first pitch and the second plurality of TSVs at the second pitch to provide TSV compression, redistribution, or both on the base die.
4. The 3D stacked memory package of clause 3,
   wherein the compression circuit comprises one or more parallel-to-serial converters, and
   wherein each parallel-to-serial converter is configured to convert multiple read signals received from multiple first TSVs of the first plurality of TSVs to a serial read signal sent to a second TSV of the second plurality of TSVs.
5. The 3D stacked memory package of clause 4, wherein the serial read signal is synchronized to a processing unit (PU) configured to receive the serial read signal through the second TSV of the second plurality of TSVs.
6. The 3D stacked memory package of any of clauses 3-5, wherein the compression circuit is configured to perform lossy data compression.
7. The 3D stacked memory package of any of clauses 1-6, wherein the compression-redistribution die comprises a memory control circuit coupled to redistribution metallizations to provide TSV compression, redistribution, or both.
8. The 3D stacked memory package of any of clauses 1-7, wherein a memory die of the plurality of memory dies is stacked face-to-face (F2F) with the compression-redistribution die.
9. The 3D stacked memory package of clause 8, wherein a back-end-of-line (BEOL) layer of the compression-redistribution die is coupled to a BEOL layer of a first memory die of the plurality of memory dies.
10. The 3D stacked memory package of any of clauses 1-9, wherein the compression-redistribution die comprises a thermal buffer.
11. The 3D stacked memory package of any of clauses 1-10, further comprising a plurality of signal TSVs extending through the base die.
12. The 3D stacked memory package of clause 11, wherein the base die comprises a physical IO interface (PHY) coupled to the plurality of signal TSVs.
13. The 3D stacked memory package of any of clauses 1-12, further comprising package bumps (304) on a backside of the base die and an array of processing units (PUs) on the base die.
14. The 3D stacked memory package of any of clauses 1-14, wherein the 3D stacked memory package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.
15. A method of forming a three-dimensional (3D) stacked memory package, the method comprising:
   stacking a plurality of memory dies on a compression-redistribution die supported by a base die, wherein the plurality of memory dies includes a first plurality of through silicon vias (TSVs) at a first pitch;
   forming a second plurality of TSVs in the compression-redistribution die at a second pitch greater than the first pitch; and
   forming compressor/redistributor blocks between the first plurality of TSVs and the second plurality of TSVs,
   wherein a number of the first plurality of TSVs is different from a number of the second plurality of TSVs.
16. The method of clause 15, wherein the compression-redistribution die comprises redistribution metallizations between the first plurality of TSVs and the second plurality of TSVs.
17. The method of any of clauses 15-16, wherein the compression-redistribution die comprises a compression circuit, a redistribution metallization, or both between the first plurality of TSV at the first pitch and the second plurality of TSV at the second pitch to provide TSV compression, redistribution, or both on the base die.
18. The method of clause 17,
   wherein the compression circuit comprises one or more parallel-to-serial converters, and
   wherein each parallel-to-serial converter is configured to convert multiple read signals received from multiple first TSVs of the first plurality of TSVs to a serial read signal sent to a second TSV of the second plurality of TSVs.
19. The 3D method of clause 18, wherein the serial read signal is synchronized to a processing unit (PU) configured to receive the serial read signal through the second TSV of the second plurality of TSVs.
20. The method of any of clauses 17-19, wherein the compression circuit is configured to perform lossy data compression.
21. The method of any of clauses 15-20, wherein the compression-redistribution die comprises a memory control circuit coupled to redistribution metallizations to provide TSV compression, redistribution, or both.
22. The method of any of clauses 15-21, wherein a memory die of the plurality of memory dies is stacked face-to-face (F2F) with the compression-redistribution die.
23. The method of clause 22, wherein a back-end-of-line (BEOL) layer of the compression-redistribution die is coupled to a BEOL layer of a first memory die of the plurality of memory dies.
24. The method of any of clauses 15-23, wherein the compression-redistribution die comprises a thermal buffer.
25. The method of any of clauses 15-24, further comprising forming a plurality of signal TSVs extending through the base die.
26. The method of clause 25, wherein the base die comprises a physical IO interface (PHY) coupled to the plurality of signal TSVs.
27. The method of clause 15, further comprising forming package bumps (304) on a backside of the base die and an array of processing units (PUs) on the base die.
28. The method of any of clauses 15-27, wherein forming the stacking the plurality of memory dies, forming the plurality of second TSVs, and forming the compressor/redistributor blocks comprise:
   wafer-to-wafer (W2W) stacking a first DRAM wafer-die on a compression-redistribution wafer-die that is face-up;
   thinning the first DRAM wafer-die to form a first memory die face-down on an active layer of the compression-redistribution wafer-die;
   W2W stacking a second DRAM wafer-die on the first memory die;
   thinning the second DRAM wafer-die form a second memory die face-down on the first memory die;
   thinning the compression-redistribution wafer-die to form the compression-redistribution die.
   stacking a base wafer-die face-down on a carrier wafer;
   thinning the base wafer-die;
   die-to-wafer (D2W) stacking a DRAM die and compression-redistribution die on the base wafer-die and contacted to an RDL, wherein the DRAM die includes the first memory die and the second memory die;
   removing the carrier wafer from the base wafer-die; and
   singulating the base wafer-die;
29. The method of any of clauses 15-27, wherein forming the stacking the plurality of memory dies, forming the plurality of second TSVs, and forming the compressor/redistributor blocks comprise:
   forming a base wafer-die face-up;
   wafer-to-wafer (W2W) stacking a first DRAM wafer-die on a compression-redistribution wafer-die that is face-up;
   thinning the first DRAM wafer-die to form a first memory die face-down on an active layer of the compression-redistribution wafer-die;
   W2W stacking a second DRAM wafer-die on the first memory die;
   thinning the second DRAM wafer-die form a second memory die face-down on the first memory die;
   die-to-wafer (D2W) stacking a DRAM die and compression-redistribution die on the base wafer-die and contacted to an RDL, wherein the DRAM die includes the first memory die and the second memory die;
   depositing an intra-die fill on the base wafer-die;
   thinning the base wafer-die; and
   singulating the base wafer-die.

For a firmware and/or software implementation, the methodologies may be implemented with modules (e.g., procedures, functions, etc.) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined may be applied to other variations without departing from the spirit or scope of the disclosure. Thus, the disclosure is not intended to be limited to the examples and designs described but is to be accorded the widest scope consistent with the principles and novel features disclosed.

What is claimed is:

1. A three-dimensional (3D) stacked memory package, comprising:
a base die;
a plurality of memory dies stacked on the base die, and including a first plurality of through silicon vias (TSVs) at a first pitch; and
a compression-redistribution die between the plurality of memory dies and the base die, the compression-redistribution die including a second plurality of TSVs at a second pitch greater than the first pitch,
wherein a number of the first plurality of TSVs is different from a number of the second plurality of TSVs.

2. The 3D stacked memory package of claim 1, wherein the compression-redistribution die comprises a redistribution metallization between the first plurality of TSVs and the second plurality of TSVs.

3. The 3D stacked memory package of claim 1, wherein the compression-redistribution die comprises a compression circuit, a redistribution metallization, or both between the first plurality of TSVs at the first pitch and the second plurality of TSVs at the second pitch to provide TSV compression, redistribution, or both on the base die.

4. The 3D stacked memory package of claim 3,
wherein the compression circuit comprises one or more parallel-to-serial converters, and
wherein each parallel-to-serial converter is configured to convert multiple read signals received from multiple first TSVs of the first plurality of TSVs to a serial read signal sent to a second TSV of the second plurality of TSVs.

5. The 3D stacked memory package of claim 4, wherein the serial read signal is synchronized to a processing unit (PU) configured to receive the serial read signal through the second TSV of the second plurality of TSVs.

6. The 3D stacked memory package of claim 3, wherein the compression circuit is configured to perform lossy data compression.

7. The 3D stacked memory package of claim 1, wherein the compression-redistribution die comprises a memory control circuit coupled to redistribution metallizations to provide TSV compression, redistribution, or both.

8. The 3D stacked memory package of claim 1, wherein a memory die of the plurality of memory dies is stacked face-to-face (F2F) with the compression-redistribution die.

9. The 3D stacked memory package of claim 8, wherein a back-end-of-line (BEOL) layer of the compression-redistribution die is coupled to a BEOL layer of a first memory die of the plurality of memory dies.

10. The 3D stacked memory package of claim 1, wherein the compression-redistribution die comprises a thermal buffer.

11. The 3D stacked memory package of claim 1, further comprising a plurality of signal TSVs extending through the base die.

12. The 3D stacked memory package of claim 11, wherein the base die comprises a physical IO interface (PHY) coupled to the plurality of signal TSVs.

13. The 3D stacked memory package of claim 1, wherein the 3D stacked memory package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, a data center, a memory device, and a device in an automotive vehicle.

14. A method of forming a three-dimensional (3D) stacked memory package, the method comprising:
stacking a plurality of memory dies on a compression-redistribution die supported by a base die, wherein the plurality of memory dies includes a first plurality of through silicon vias (TSVs) at a first pitch;
forming a second plurality of TSVs in the compression-redistribution die at a second pitch greater than the first pitch; and
forming compressor/redistributor blocks between the first plurality of TSVs and the second plurality of TSVs,
wherein a number of the first plurality of TSVs is different from a number of the second plurality of TSVs.

15. The method of claim 14, wherein the compression-redistribution die comprises a compression circuit, a redistribution metallization, or both between the first plurality of TSV at the first pitch and the second plurality of TSV at the second pitch to provide TSV compression, redistribution, or both on the base die.

16. The method of claim 15,
wherein the compression circuit comprises one or more parallel-to-serial converters, and
wherein each parallel-to-serial converter is configured to convert multiple read signals received from multiple first TSVs of the first plurality of TSVs to a serial read signal sent to a second TSV of the second plurality of TSVs.

17. The method of claim 14, wherein the compression-redistribution die comprises a thermal buffer.

18. The method of claim 14, further comprising forming a plurality of signal TSVs extending through the base die.

19. The method of claim 14, wherein forming the stacking the plurality of memory dies, forming the plurality of second TSVs, and forming the compressor/redistributor blocks comprise:
wafer-to-wafer (W2W) stacking a first DRAM wafer-die on a compression-redistribution wafer-die that is face-up;
thinning the first DRAM wafer-die to form a first memory die face-down on an active layer of the compression-redistribution wafer-die;
W2W stacking a second DRAM wafer-die on the first memory die;
thinning the second DRAM wafer-die form a second memory die face-down on the first memory die;
thinning the compression-redistribution wafer-die to form the compression-redistribution die;
stacking a base wafer-die face-down on a carrier wafer;
thinning the base wafer-die;
die-to-wafer (D2W) stacking a DRAM die and compression-redistribution die on the base wafer-die and contacted to an RDL, wherein the DRAM die includes the first memory die and the second memory die;
removing the carrier wafer from the base wafer-die; and
singulating the base wafer-die.

20. The method of claim 14, wherein forming the stacking the plurality of memory dies, forming the plurality of second TSVs, and forming the compressor/redistributor blocks comprise:
forming a base wafer-die face-up;
wafer-to-wafer (W2W) stacking a first DRAM wafer-die on a compression-redistribution wafer-die that is face-up;
thinning the first DRAM wafer-die to form a first memory die face-down on an active layer of the compression-redistribution wafer-die;
W2W stacking a second DRAM wafer-die on the first memory die;
thinning the second DRAM wafer-die form a second memory die face-down on the first memory die;
die-to-wafer (D2W) stacking a DRAM die and compression-redistribution die on the base wafer-die and contacted to an RDL, wherein the DRAM die includes the first memory die and the second memory die;
depositing an intra-die fill on the base wafer-die;
thinning the base wafer-die; and
singulating the base wafer-die.
